(19) United States
(12) Patent Application Publication
(10) Pub. No.: US 2019/0173156 A1
(43) Pub. Date: Jun. 6, 2019

(54) SENSOR

(71) Applicant: The University of Manchester, Manchester (GB)

(72) Inventor: Zhirun HU, Manchester (GB)

(21) Appl. No.: 16/306,750

(22) PCT Filed: Jun. 2, 2017
(86) PCT No.: PCT/GB2017/051590

§ 371 Date: Dec. 3, 2018

(30) Foreign Application Priority Data
Jun. 3, 2016 (GB) 1609730.5

(51) Int. Cl. H01Q 1/22; H01P 5/04; H01P 7/08; C01B 32/182; H03H 7/38

(52) U.S. Cl. CPC H01Q 1/2225; H01P 5/04; H01P 7/082; C01B 2204/04; H03H 7/38; C01B 2204/02; C01B 32/182

(57) ABSTRACT

This invention relates to sensors and, in particular radio-frequency identification (RFID) tags. The sensors comprise oxygenated graphene which is arranged to alter the electrical properties of an electrical system in response to a change in environmental conditions. A particular advantage of the present invention is that the sensor can be assembled layer by layer to fabricate a multifunctional sensor. A multi-functional sensor may comprise multiple regions of different sensing materials that can sense different environmental changes.

This invention relates to sensors and, in particular radio-frequency identification (RFID) tags. The sensors comprise oxygenated graphene which is arranged to alter the electrical properties of an electrical system in response to a change in environmental conditions.

### BACKGROUND

There is a need for improved sensors for measuring environmental conditions, such as humidity, temperature and the presence of chemical compounds. Applications of such sensors include monitoring industrial processes e.g. reaction vessels, monitoring conditions in which sensitive materials are handled, monitoring exhaust gases or other localized environments in vehicles, monitoring atmospheric conditions both externally and in buildings, medical devices etc.

Viewed from a first aspect, there is provided a sensor, the sensor comprising:

an electrical circuit; and

at least one region of oxygenated graphene in electrical contact with the electrical circuit, optionally wherein an insulator of less than 100 μm thickness is present between the electrical circuit and the oxygenated graphene, and wherein the oxygenated graphene is arranged to alter the electrical properties of the circuit in response to environmental changes experienced by the oxygenated graphene.

Thus, the sensor of the first aspect may or may not comprise an insulator of less than 100 μm thickness present between the electrical circuit and the oxygenated graphene. In one embodiment the insulator is present. In an alternative embodiment, the insulator is not present. In the case in which the insulator is not present, the oxygenated graphene may still be arranged to alter the electrical properties of the circuit in response to environmental changes experienced by the oxygenated graphene. In this case the oxygenated graphene is in direct contact with the electrical circuit.

Electrical contact in this context thus also includes the situation in which there is a thin insulation layer between the electrical circuit and oxygenated graphene, as well as the case in which no insulator is present, since the circuit will still be operable when a thin insulating layer is present. For the purposes of this aspect and others relating to the sensor, the sensor may be constructed with the electrical circuit being in direct electrical contact (i.e. electrical contact) with the oxygenated graphene or it may be constructed using a thin insulation layer between the sensor and the oxygenated graphene. The electrical insulator, when present, is usually less than 100 μm thick, and more preferably it is less than 50 μm thick, more preferably less than 10 μm or even more preferably less than 1 μm thick. There is no need for oxygenated graphene to contact the antenna directly. The gap between the GO and the sensor should be small so to have strong coupling between the two. The smaller the gap the more sensitive it will be. Direct contact is the extreme case when the two move closer and closer.

The environmental change experienced by the oxygenated graphene may include a change in humidity, temperature, and/or the presence or level of a chemical agent. The environmental change experienced by the oxygenated graphene may include a change in the presence or level of a chemical agent. The chemical agent will typically be a gas or a vapour. Gases which may influence sensor and invoke a response include; air, oxygen, carbon monoxide, carbon dioxide, and oxides of nitrogen. Exemplary chemical agents include carbon monoxide, carbon dioxide and/or other products of combustion processes. Exemplary chemical agents include volatile organic compounds, e.g. solvents, monomers or reactants. Alcohols such as simple aliphatic alcohols like methanol and ethanol may also invoke a response. Water vapour i.e. moisture is also an exemplary agent that may invoke a response.

Combining a sensor with a means for identifying the sensor provides not only the information about the environmental conditions at the sensors location but also the identity of the sensor, making it possible to monitor each individual object and get a complex picture of how environmental conditions vary from one location in a monitored environment to the other. Thus, RFID combined with sensor-enabled tags having ambient environment sensing ability, as well as allowing wireless identification of the tags, can find wide applications in daily life, simplifying information gathering and collection infrastructure in appropriate contexts.

The environmental change experienced by the oxygenated graphene may include a change in humidity. The environmental change experienced by the oxygenated graphene may include a change in temperature. The environmental change may also include a combination of these factors i.e. a change in both temperature and humidity. The changes due to a combination can be calibrated from knowledge of the response of the oxygenated graphene to the individual stimuli of temperature and humidity. Environmental changes may also separately, or in addition, include the presence or absence of a chemical entity. This entity might typically be in the form of a liquid or gas.

The at least one oxygenated graphene region preferably comprises a plurality of oxygenated graphene flakes. The flakes may be arranged in the form of a laminate of stacked oxygenated graphene flakes. The oxygenated graphene region may be a coating, e.g. a printed coating.

The oxygenated graphene flakes may be a single atomic layer thick. However, it is possible to use oxygenated graphene flakes which are from 2 to 10 atomic layers thick.

It may be that greater than 50% by weight (e.g. greater than 75% by weight, greater than 90% or greater than 98%) of the oxygenated graphene flakes have a diameter of less than 10 μm. It may be that greater than 50% by weight (e.g. greater than 75% by weight, greater than 90% or greater than 98%) of the oxygenated graphene flakes have a diameter of greater than 50 nm. It may be that greater than 50% by weight (e.g. greater than 75% by weight, greater than 90% or greater than 98%) of the oxygenated graphene flakes have a diameter of less than 5 μm. It may be that greater than 50% by weight (e.g. greater than 75% by weight, greater than 90% or greater than 98%) of the oxygenated graphene flakes have a diameter of greater than 100 nm. It may be that greater than 50% by weight (e.g. greater than 75% by weight, greater than 90% or greater than 98%) of the oxygenated graphene flakes have a diameter of less than 2 μm. It may be that greater than 50% by weight (e.g. greater than 75% by weight, greater than 90% or greater than 98%) of the oxygenated graphene flakes have a diameter of greater than 200 nm.

It may be that greater than 50% by weight (e.g. greater than 75% by weight, greater than 90% or greater than 98%) of the oxygenated graphene has a thickness of from 1 to 10 atomic layers. It may be that greater than 50% by weight (e.g. greater than 75% by weight, greater than 90% or greater than 98%) of the oxygenated graphene has a thickness of from 1 to 5 molecular layers. Thus, it may be that greater than 50% by weight (e.g. greater than 75% by weight, greater than 90% or greater than 98%) of the oxygenated graphene has a thickness of from 1 to 3 molecular layers. It may be that greater than 50% by weight (e.g. greater than 75% by weight, greater than 90% or greater than 98%) of the oxygenated graphene has a thickness of from 2 to 5 molecular layers.

The at least one region (e.g. coating) of oxygenated graphene may be a single oxygenated graphene flake thick. The electrical properties of oxygenated graphene flake can change relative to the amount of various chemical substances adsorbed onto the flakes. For certain applications, e.g. in sensors that detect humidity levels, however, it is preferable that the at least one region is more than one flake thick. Water vapour can fill capillary like pores between oxygenated graphene flakes and it is this process that changes the electrical properties of the bulk sample. Thus, the at least one region of oxygenated graphene may be from 2 to 200 oxygenated graphene flakes thick. The region (e.g. coating) may be from 5 to 100 oxygenated graphene flakes thick. The at least one region (e.g. coating) may be from 10 to 50 oxygenated graphene flakes thick. Thus, the at least one region of oxygenated graphene may be from 10 nm to 100 μm thick. The at least one region (e.g. coating) may be from 25 nm to 1 μm thick. The at least one region (e.g. coating) may be from 1 μm to 100 μm thick.

The electrical property of the circuit that is altered in response to the environmental changes may be the resistivity of the region of oxygenated graphene. Although oxygenated graphene is itself a substantially dielectric material, the adsorption of certain chemical substances or water may introduce a degree of electronic conductivity across a region of oxygenated graphene. Thus, in one simple embodiment, the invention relates to an electrical circuit including a resistor comprising a region of oxygenated graphene placed in the circuit and arranged such that current flows through the resistor. A change in the resistance of the resistor can be sensed by determining changes in the current flowing through the resistor, and a change in temperature, the presence and/or degree of water (humidity) or other chemical substances may be inferred from the change in resistance.

In another simple embodiment, a capacitor may be configured by situating the oxygenated graphene between two conductive plates. The graphene and the conductive plates thus act as a capacitor and the electrical property of the circuit that are altered in response to the environmental changes is the capacitance of this capacitor. Such capacitor based arrangements are typically more sensitive than the simple resistance measurement arrangement mentioned above. Where the sensor is intended for testing humidity or the presence of a chemical entity, it may be for example that the surface of the respective plates that face the other plate are coated in oxygenated graphene and that the atmosphere that there is a gap between the respective oxygenated graphene coatings, said gap being in fluid communication with the atmosphere that is being tested.

Viewed from a second aspect, there is provided an antenna suitable for an RFID transponder, wherein the antenna is in electrical contact with at least one region of oxygenated graphene, optionally wherein an insulator of less than 100 μm thickness is present between the antenna and the oxygenated graphene, and wherein the oxygenated graphene is arranged to alter the electrical properties of the antenna in response to environmental changes experienced by the oxygenated graphene.

Thus, the antenna of the second aspect may or may not comprise an insulator of less than 100 μm thickness present between the electrical circuit and the oxygenated graphene. In one embodiment the insulator is present. In an alternative embodiment, the insulator is not present. In the case in which the insulator is not present, the oxygenated graphene may still be arranged to alter the electrical properties of the circuit in response to environmental changes experienced by the oxygenated graphene.

As before, electrical contact in this context thus also includes the situation in which there is a thin insulation layer between the antenna and oxygenated graphene since the antenna will still be effective when a thin insulating layer is present. For the purposes of this aspect and others relating to the antenna, the antenna may be constructed with the antenna being in direct electrical contact (i.e. electrical contact) or it may be constructed using a thin insulation layer between the antenna and the oxygenated graphene. The electrical insulator, when present, is usually less than 100 μm thick, and more preferably it is less than 50 μm thick, more preferably less than 10 μm or even more preferably less than 1 μm thick. There is no need for oxygenated graphene to contact the antenna directly. The gap between the GO and the antenna should be small so to have strong coupling between the two. The smaller the gap the more sensitive it will be. Direct contact is the extreme case when the two move closer and closer.

Viewed from a third aspect, there is provided an RFID transponder comprising: an antenna for communicating with an RFID reader;

an RFID chip coupled to the antenna; and

at least one region of oxygenated graphene in electrical contact with the antenna, optionally wherein an insulator of less than 100 μm thickness is present between the antenna and the oxygenated graphene, and wherein the oxygenated graphene is arranged to alter the electrical properties of the antenna in response to environmental changes experienced by the oxygenated graphene.

As with the various aspects described earlier, electrical contact in this context also includes the situation in which there is a thin insulation layer between the antenna and oxygenated graphene and the same comments apply here as to the previous aspects with reference to the insulator.

It may be that the electrical properties of the antenna altered by the oxygenated graphene comprise one or more of a resonant frequency of the antenna, an input impedance of the antenna, or a minimum scattering power of the antenna in response to environmental changes experienced by the oxygenated graphene.

In certain specific examples, changes in humidity, temperature, and/or the presence or level of a chemical agent cause a change in the relative permittivity of the oxygenated graphene. This, in turn, effects a change in the electrical properties of the antenna.

In certain specific examples, the antenna comprises graphene, e.g. a printed graphene.

The at least one region of oxygenated graphene may be a coating on the antenna or on part of the antenna. Alternatively, the at least one region of oxygenated graphene may be embedded in a part of the antenna or disposed between conductive parts of the antenna. The antenna may be an RFID tag. The RFID tag may comprise two regions of oxygenated graphene in contact with the antenna. The two regions of oxygenated graphene may be arranged at opposite ends of the antenna.

The antenna may comprise printed graphene coated with at least one region of oxygenated graphene.

It may be that the RFID transponder is configured to switch off in response to environmental changes experienced by the oxygenated graphene.

It may be that the RFID tag is configured to switch on/off to two different states in response to environmental changes experienced by the oxygenated graphene.

It may be that the antenna and the at least one region of oxygenated graphene form a heterostructure.

The antenna may be suitable for communicating with an RFID reader.

It may be that the RFID transponder comprises a flexible substrate on which one or more of the antenna, the RFID chip, and at least one region of oxygenated graphene is disposed.

Viewed from a fourth aspect, there is provided a wireless system, comprising an RFID reader and an RFID transponder according to the third aspect.

Viewed from a fifth aspect, there is provided a method of detecting an environmental change, the method comprising:

detecting a change in the electrical properties of the circuit of a sensor of the first aspect, an antenna of the second aspect or an RFID transponder of the third aspect,

comparing the detected change with reference data; and

determining an environmental change based on the comparison of the detected change and the reference data.

It may be that the sensor is an RFID transponder according to the third aspect and the method comprises:

exciting the RFID transponder using a first electromagnetic signal;

receiving a re-transmitted second electromagnetic signal from the RFID tag;

comparing the second electromagnetic signal with reference data; and

determining an environmental change based on the comparison of the second electromagnetic signal and the reference data.

The reference data may be obtained by receiving a reference electromagnetic signal from the RFID transponder when the RFID transponder is experiencing one or more known environmental conditions.

The circuit in which the sensor, antenna or RFID is incorporated may be passive, active or battery assisted passive. The circuit may be a passive circuit, such as a battery free RFID; a wireless active RFID sensing and control circuit; a battery-free UHF and NFC RFID sensing and control circuit; a remote humidity control circuit; a multi-sensing and control circuit; a sensing and actuating circuit; or an RF ambient energy powered low power sensing and control circuit.

A particular advantage of the present invention is that the sensor can be assembled layer by layer to fabricate a multifunctional sensor. A multi-functional sensor may comprise multiple regions of different sensing materials that can sense different environmental changes. A multi-functional sensor such as an integrated humidity, temperature and/or chemical sensor can be fabricated using this layer by layer assembly method. A multi-functional sensor may comprise multiple regions of different sensing materials, such as separate regions of oxygenated graphene, with some regions of oxygenated graphene having different levels of oxygen present. A multifunctional sensor may therefore comprise one of more regions of graphene oxide, reduced graphene oxide, partially oxidised graphene oxide and combinations thereof.

The embodiments described above in relation to the first aspect of the invention apply equally, where not mutually exclusive, to the second, third, fourth and fifth aspects of the invention.

By combining sensing capabilities with RFID identification techniques, certain embodiments have excellent practical applications. The measurement results clearly reveal that the electrical properties of oxygenated graphene, for example relative permittivity and loss tangent, change with ambient humidity. Other environmental changes may also have an effect of the electrical properties of oxygenated graphene. The changes of these properties, and hence changes in environmental conditions, can be detected both by wire and wirelessly.

These detected properties may be quantitatively estimated through experiments and simulations on resonators coated or otherwise provided with regions of oxygenated graphene. In addition, the graphene RFID tags provided with an oxygenated graphene coating or the like have been found to experience different backscattered signal phase shifts when the humidity changes. This means that humidity can be detected wirelessly through oxygenated graphene sensing.

Other environmental conditions such as temperature or the presence of certain chemicals may also be detected in this way. RFID combined with sensor-enabled tags having ambient environment sensing ability, as well as allowing wireless identification of each tag, can find wide application in daily life.

### BRIEF DESCRIPTION OF THE DRAWINGS

Embodiments of the invention are further described hereinafter with reference to the accompanying drawings, in which:

FIG. 1 shows: (a) a sealed box setup for graphene oxide (GO) permittivity measurement (the top cover of the box has been removed for a better view) and (b) measured and simulated transmission coefficients (S₂₁) of the samples with/without GO coating. The thickness of the GO layer is 30 μm.

FIG. 2 shows: (a) resonance frequency as function of relative humidity (RH) and (b) Relative permittivity (εᵣ=ε′−iε″) and loss tangent (tan δ=ε″/ε′) of the GO under various RH.

FIG. 3 shows the operating principle of the GO based RFID sensor system. The GO coating thickness of the top right sensing tag is 10 μm.

FIG. 4 shows: (a) measured backscattered signal phases with various humidity as function of frequency, (b) enlarged backscattered signal phases at 910 MHz as function of humidity and (c) enlarged backscattered signal phase at 900 MHz as function of humidity.

FIG. 5 shows: (a) a microstrip resonator without GO coating, (b) microstrip resonator with GO coating (a 30 μm thick GO layer was deposited on the capacitor area (15 mm×8 mm) of the resonator) and (c) its simulated and measured transmission coefficients.

FIG. 6 shows the simulated transmission coefficients (S₂₁) of the resonator covered by dielectric layers of various relative permittivities (and E).

FIG. 7 shows the experimental setup for a wireless radio frequency identification (RFID) GO humidity sensing system.

### DETAILED DESCRIPTION

Oxygenated graphene is intended to refer to any oxygenated graphene material. Graphene consists of a layer of sp² hybridised carbon atoms. Each carbon atom is covalently bonded to three neighbouring carbons to form a network of tessellated hexagons. Oxygenated graphene materials have oxygen atoms attached to these carbon atoms. The oxygen atoms may take the form of epoxide groups, hydroxyl groups, ketone groups, carboxylic acid groups, etc. The oxygenated graphene thus may comprise a plurality of different oxygen-containing functional groups. Exemplary functional groups include but are not limited to: carboxyl, carbonyl, epoxide, hydroxyl, ether, and ester. The oxygenated graphene may comprise a plurality of the same functional group, e.g. a plurality of carboxyl groups but, more usually, the plurality of functional groups comprises two or more different groups, e.g. the oxygenated graphene may comprise a plurality of carboxylic acid groups and a plurality of epoxide groups and/or ester groups and/or carbonyl groups. The functional groups may be connected to the graphene either directly or indirectly through covalent or non-covalent means. Preferably however they are covalently attached to the graphene. Preferably they are directly attached to the graphene. Typically, in oxygenated graphene materials this network of tessellated hexagons comprises defects in which carbon atoms form more than one bond to a single oxygen atom and/or form bonds to more than one oxygen atom.

Throughout this specification the term ‘oxygenated graphene’ may encompass any graphene like material that comprises more than 1% oxygen by weight, 5% or more oxygen by weight, e.g. 10% or more, or 20% or more oxygen by weight, or even 25% or more oxygen by weight. Thus, the term ‘oxygenated graphene’ may refer to graphene oxide, reduced graphene oxide, partially oxidised graphene etc. In an embodiment, the amount of oxygen in the oxygenated graphene may be up to 60% oxygen by weight, for example from 1% to 60% oxygen by weight, 10% to 50% oxygen by weight, or 10% to 40% oxygen by weight, and is preferably from 20% to 30% oxygen by weight. In an alternative series of embodiments, the amount of oxygen in the oxygenated graphene may be from 1% to 5% oxygen by weight, for example from 1% to 2%, 3%, or 4% oxygen by weight,

The oxygenated graphene flakes may be a single atomic layer thick. However, it is possible to use oxygenated graphene flakes which are from 2 to 10 atomic layers thick. These multilayer flakes are frequently referred to as “few-layer” flakes. Thus the oxygenated graphene present in the coating may be present entirely as monolayer flakes, as a mixture of monolayer and few-layer flakes, or entirely as few-layer flakes.

The oxygenated graphene for use in this application can be made by any means known in the art. In one method, graphite oxide can be prepared from graphite flakes (e.g. natural graphite flakes) by treating them with potassium permanganate and sodium nitrate in concentrated sulphuric acid. This method is called Hummers method. Another method is the Brodie method, which involves adding potassium chlorate (KClO₃) to a slurry of graphite in fuming nitric acid. For a review see, Dreyer et al. The chemistry of graphene oxide, Chem. Soc. Rev., 2010, 39, 228-240. The graphite flakes may be natural graphite or it may be pre-activated (‘worm-like’) graphite flakes, depending on the level of oxygenation desired.

Individual graphene oxide (GO) sheets can then be exfoliated by dissolving graphite oxide in water or other polar solvents with the help of ultrasound, and bulk residues can then be removed by centrifugation and optionally a dialysis step to remove additional salts.

The oxygenated graphene may be reduced graphene oxide. It may be that a suspension of graphene oxide flakes is reduced to form a suspension of reduced graphene oxide flakes which is subsequently deposited to provide a region of reduced graphene oxide. Alternatively, it may be that a suspension of graphene oxide flakes is deposited to provide a region of graphene oxide and that the graphene oxide coating is subsequently reduced to provide a region of reduced graphene oxide on the substrate. The reduction may be conducted, for example, using a metal hydride reducing agent (e.g. LiAlH₄ or NaBH₄), ascorbic acid, HI or hydrazine. Thermal or microwave assisted reductions are also possible. A discussion of the various methods available for the reduction of graphene oxide can be found in Chua and Pumera; ‘Chemical Reduction of Graphene Oxide: A Synthetic Chemistry Viewpoint’ Chem. Soc. Rev. 2013. Where the oxygenated graphene is reduced graphene oxide or partially oxidised graphene, the oxygen level may be lower than in graphene oxide. For example, the amount of oxygen in the oxygenated graphene may be less than 10% oxygen by weight or less than 5% oxygen by weight, for example 1% to 10% oxygen by weight, 1% to 5% oxygen by weight. The oxygenated graphene may comprise 1%, 2%, 3%, 4% or 5% oxygen by weight or any subrange within those values.

It may be that the sensor, antenna or RFID according to the invention comprise separate regions of oxygenated graphene with differing levels of oxygen. For example, the sensor, antenna or RFID may comprise separate regions of graphene oxide and regions of reduced graphene oxide. The use of separate regions with different levels of oxygenated graphene may allow concurrent sensing of multiple environmental changes described herein in a multifunctional sensor.

It may be that the sensor, antenna or RFID according to the invention comprise separate regions of oxygenated graphene in which the separate regions of oxygenated graphene have the same or similar levels of oxygen.

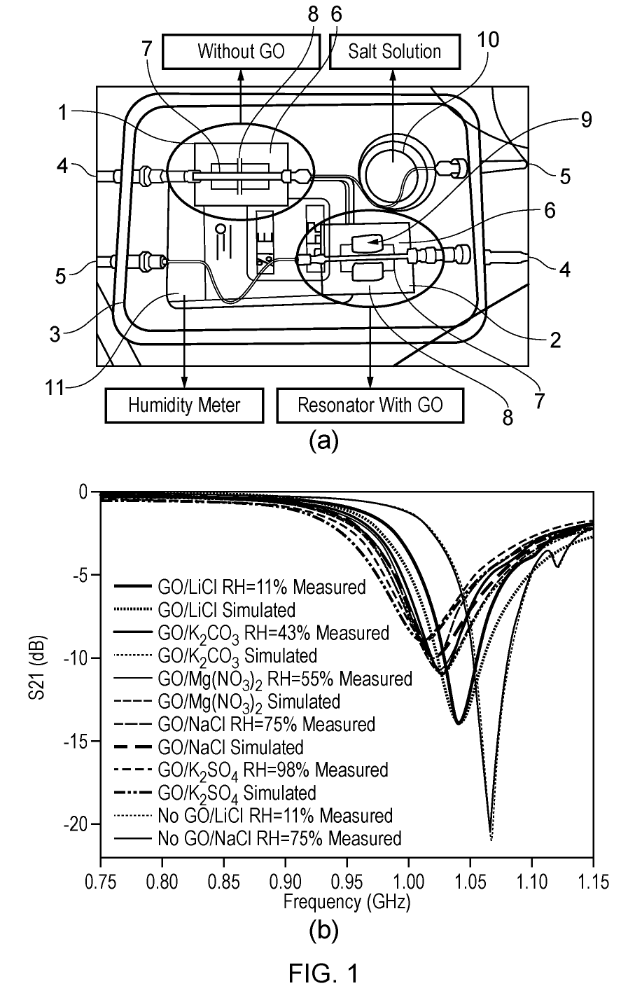

FIG. 1(a) shows an experimental set-up for determining changes to the relative permittivity of oxygenated graphene due to humidity. Permittivity is the measure of resistance that is encountered when forming an electric filed in a particular medium. It is a measure of the amount of charge needed to generate one unit of electric flux in the medium. Permittivity can be separated into real and imaginary parts, the imaginary part corresponding with the impedance of a dielectric medium and the real part having a greater effect on the capacitance of the material. The change in capacitance of the material provides a useful response which can be detected.

First and second microstrip resonators 1, 2 are arranged in a container 3 and respectively provided with RF input and output connections 4, 5. Each microstrip resonator comprises a dielectric substrate 6 with a conductive groundplane (not visible in the Figure) on the underside and a microstrip transmission line 7 on the topside, connected between the RF input and output connections 4, 5. A capacitor 8 is additionally formed by conductive tracks formed between the RF input and output connections 4, 5. The capacitor 8 on the first microstrip resonator 1 is not loaded. In contrast, the capacitor 8 on the second microstrip resonator 2 is coated with oxygenated graphene 9, which serves to provide a dielectric loading to the capacitor 8. A dish 10 of salt solution is provided in the container 3 to provide a controllable source of humidity, and a lid (not shown in the Figure) allows the container 3 to be sealed in an airtight manner. A standard humidity meter 11 is also provided in the container 3 to allow an independent measurement of the humidity.

FIG. 1(b) is a plot of the S21 frequency response measured as power loss between ports 5 and 4 for both microstrip resonators 1, 2 for various different salt solutions and relative humidities. It can be seen that the resonant frequency of the microstrip resonator 2 with the oxygenated graphene coating 9 changes with relative humidity, whereas the resonant frequency of the microstrip resonator 1 without the oxygenated graphene coating remains substantially constant.

In the measurement, five salt solutions were used, which provided RH from 11% to 98%. To get accurate and stable RH as well as sufficient exposure of oxygenated graphene to water vapor, the transmission coefficients of the two resonators 1, 2 were measured after the humidity meter 11 had given a constant humidity reading for 24 hours. The measured transmission coefficients for the samples with and without the oxygenated graphene coating 9 are shown in FIG. 1(b), together with the simulated results for permittivity extraction. From the measured results, it is clear that the resonator 2 with the oxygenated graphene coating 9 has responded to the humidity changes, whereas the resonator 1 without the oxygenated graphene has not. The different responses of these two resonators 1, 2 can only be caused by the change of oxygenated graphene properties due to humidity. For the resonator 2 with the oxygenated graphene coating 9, it can be observed that the resonance frequency shifts to lower frequency and its fractional bandwidth increases as the RH rises. This reveals that not only the real part of the relative permittivity (c′) of the oxygenated graphene increases but that its imaginary part (c′) also rises as the oxygenated graphene absorbs more water vapor.

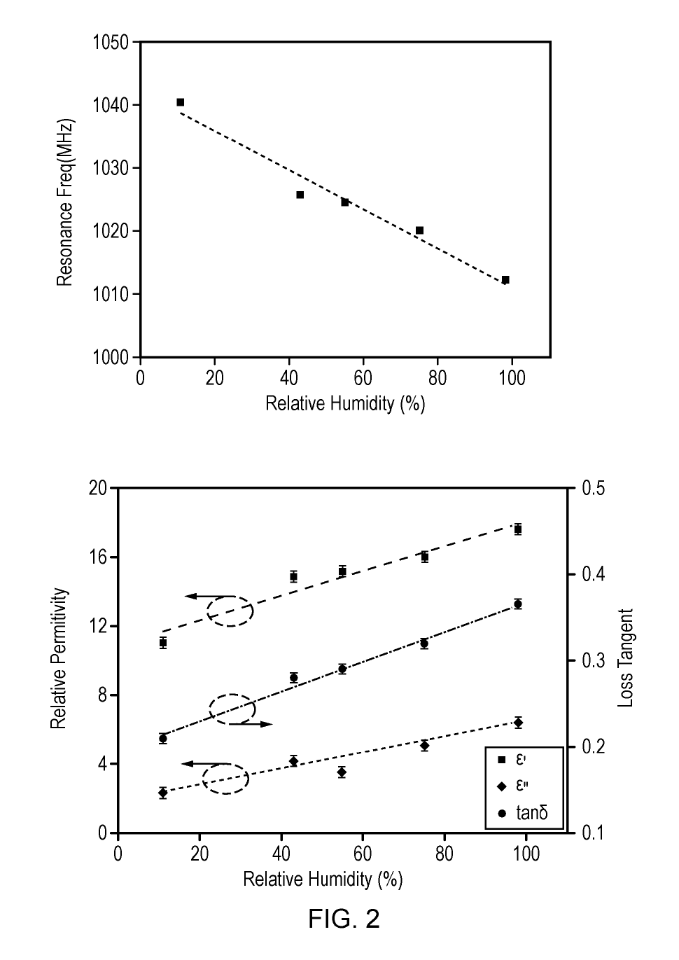

The simulated and measured resonance frequency as a function of the RH is illustrated in FIG. 2(a). Furthermore, by comparing simulated and measured results under different humidities, the relationship between the relative permittivity (εᵣ=ε′−ε″) of the oxygenated graphene 9 (as well as the loss tangent (tan δ=ε″/ε′)) and the RH can be obtained as shown in FIG. 2(b). It can be seen that ε′ and ε″ of the oxygenated graphene 9 change from about 11 to 17.6 and 2.3 to 6.4, respectively, as RH varies from 11% to 98%. Correspondingly, the loss tangent tan δ increases from 0.21 to 0.37. As can be seen from FIG. 2(b), the real part of the permittivity changes at a rate of more than 0.5 per 10% change in RH.

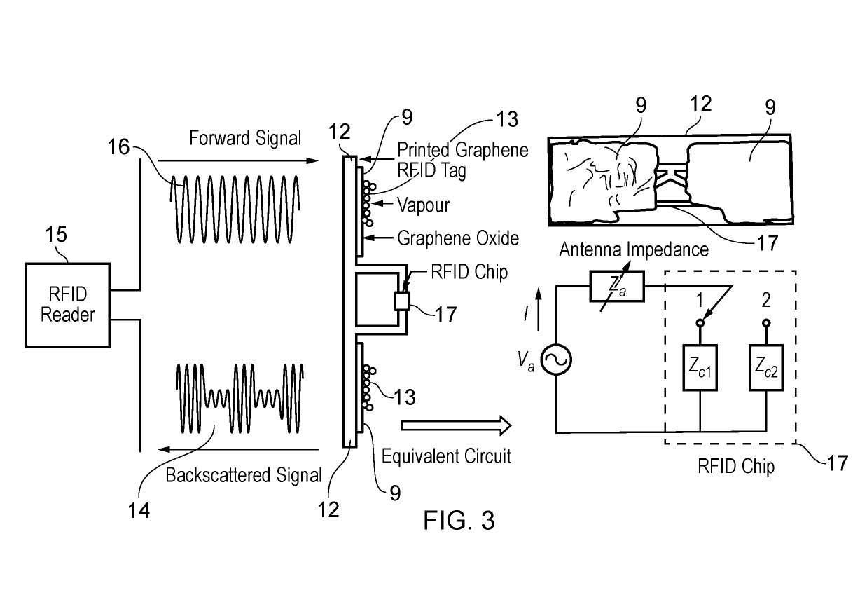

With reference to FIG. 3, an RFID antenna 12 is electrically-small and prone to proximity effects such as material property changes. An RFID antenna 12 may be formed as a printed graphene RFID antenna. When oxygenated graphene 9 coated on a printed graphene RFID antenna 12 absorbs vapour 13, its permittivity changes, which alters the antenna impedance. The backscattering signal 14 phase changes accordingly and can be detected by an RFID reader 15. When the RFID reader 15 transmits an electromagnetic wave signal 16 (also called ‘forward electromagnetic wave signal’) to the RFID antenna 12, the antenna draws energy from this forward signal and activates the RFID chip 17 on the antenna 12. The backscattered signal 14 is both amplitude and phase modulated by the RFID chip 17 through varying the input impedance of the chip 17. Modulation occurs as the RFID chip 17 rapidly switches between two discrete impedance states. The operating principle is shown in FIG. 3, where an oxygenated graphene coated RFID sensing tag 12 is shown at top right and an equivalent circuit is shown bottom right to explain illustrate the amplitude and phase modulation.

In RFID antenna design, antenna 12 impedance is typically conjugately matched to the higher impedance state of the chip 17 in order to maximize the collected power. The equivalent Thevenin open source voltage Vₐ on the antenna can be given as

Vₐ=\sqrt{8P_{Ant}Re(Zₐ)} (1)

where P_{Ant} is the power available at the antenna port, Z_{α} is the antenna impedance. The switching between the two input impedance states Z_{C1} and Z_{C2} generates two different currents at the antenna port, which can be calculated as:

$$\begin{matrix}{I}_{1} = {V}_{a} ( \frac{1}{{Z}_{a} + {Z}_{C 1}} ) & ( 2 ) \\ {I}_{2} = {V}_{a} ( \frac{1}{{Z}_{a} + {Z}_{C 2}} ) & ( 3 )\end{matrix}$$

When the humidity changes, the oxygenated graphene layer 9 on the RFID antenna 12 changes its electrical property, in this case its permittivity. This change alters the antenna impedance Zₐ. As Zₐ changes, so do I₁ and I₂, causing the backscattered signal 14 phase to vary accordingly. The backscattered signal 14 phase can be detected by the RFIF reader 15.

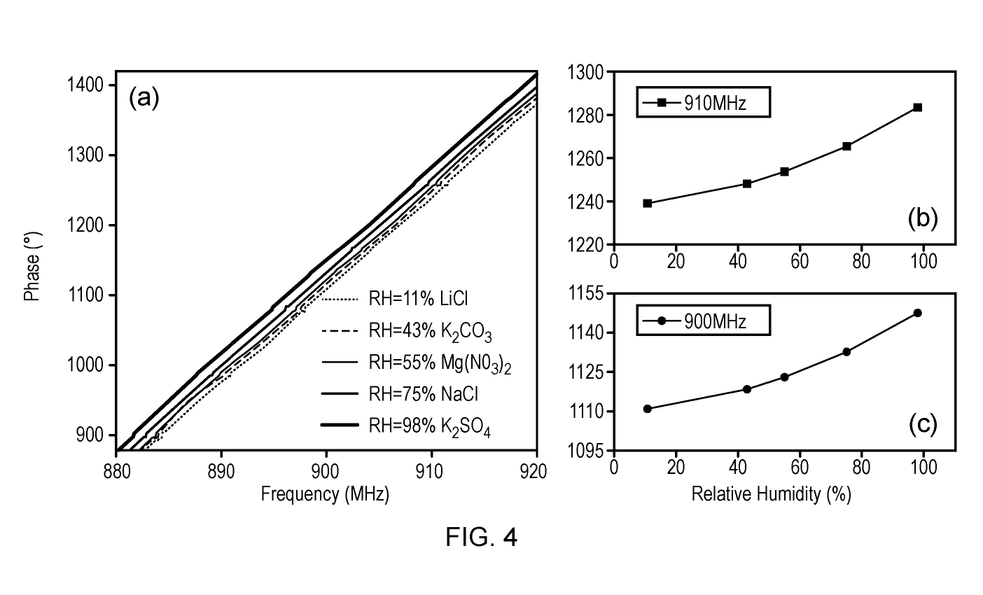

FIG. 4 shows measurements of the backscattered signal phase using Voyantic Tagformance under different humidity conditions.

From FIG. 4(a), it can be seen that the humidity has a clear effect on the backscattered signal phase in a typical RFID frequency spectrum from 880 MHz to 920 MHz, which experimentally proves that the backscattered signal 14 contains humidity information. Enlarged phase information is shown in FIGS. 4(b) and 4(c) at 910 MHz and 900 MHz, respectively, to illustrate the sensitivity of the oxygenated graphene RFID sensor 12 for detecting humidity changes. As it can be seen from FIGS. 4(b) and 4(c), the backscattered 910 MHz and 900 MHz signal phases increase by 44.6° and 39.5° respectively, as RH rises from 11% to 98%. For the 910 MHz signal, an average phase change of 0.5° for every 1% increase in RH can be observed, unambiguously demonstrating the effectiveness of wireless printed graphene enabled RFID oxygenated graphene humidity detection.

### Examples

### Preparation of Oxygenated Graphene Coating

A modified Hummers method was employed in order to prepare graphene oxide. Briefly, 4 grams of graphite was mixed with 2 grams of NaNO₃ and 92 mL of H₂SO₄. KMNO₄ was subsequently added in incremental steps in order to achieve a homogeneous solutions. The temperature of the reaction was monitored and kept near 100° C. The mixture was then diluted by 500 mL of deionised water and 3% H₂O₂. The resulting solution was washed by repeated centrifugation until the pH of the solution was around 7. The graphene oxide was then diluted to the required concentration.

For the purpose of coating the RFID tags with graphene oxide, a 10 grams per litre viscous graphene oxide solution was used. This allowed direct screen printing of the graphene oxide on the paper tag, which was left to dry overnight in a fume hood under continuous air flow.

### Permittivity Extraction

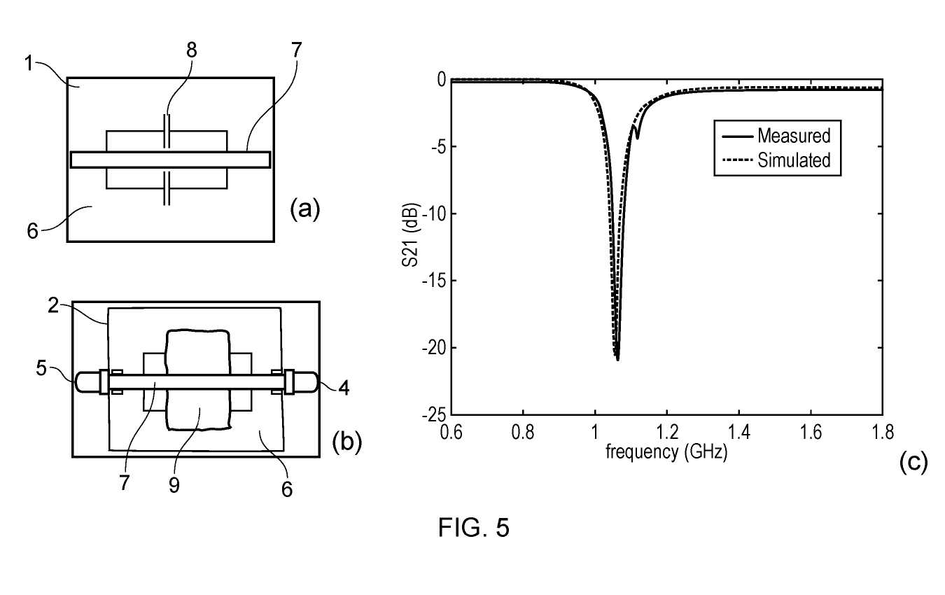

FIG. 5(a) shows a test resonator 1 for graphene oxide permittivity measurement and extraction. The test resonator 2 comprises a dielectric substrate 6 with a conductive groundplane (not visible in the Figure) on the underside and a microstrip transmission line 7 on the topside. A capacitor 8 is additionally formed by conductive tracks formed on the dielectric substrate 6. FIG. 5(b) shows another test resonator 2, identical to the test resonator 1 of FIG. 5(a) but with the capacitor 8 coated with graphene oxide 9, which serves to provide a dielectric loading to the capacitor 8. FIG. 5(b) also shows the microstrip transmission line 7 and the capacitor 8 connected between RF input and output connections 4, 5

To validate the full electromagnetic wave simulation (CST Microwave Studio), the simulated and measured transmission coefficients of the resonator 1 without the graphene oxide coating are shown in FIG. 5(c). It can be seen that the simulated results agree very well with the measured ones, validating the simulation.

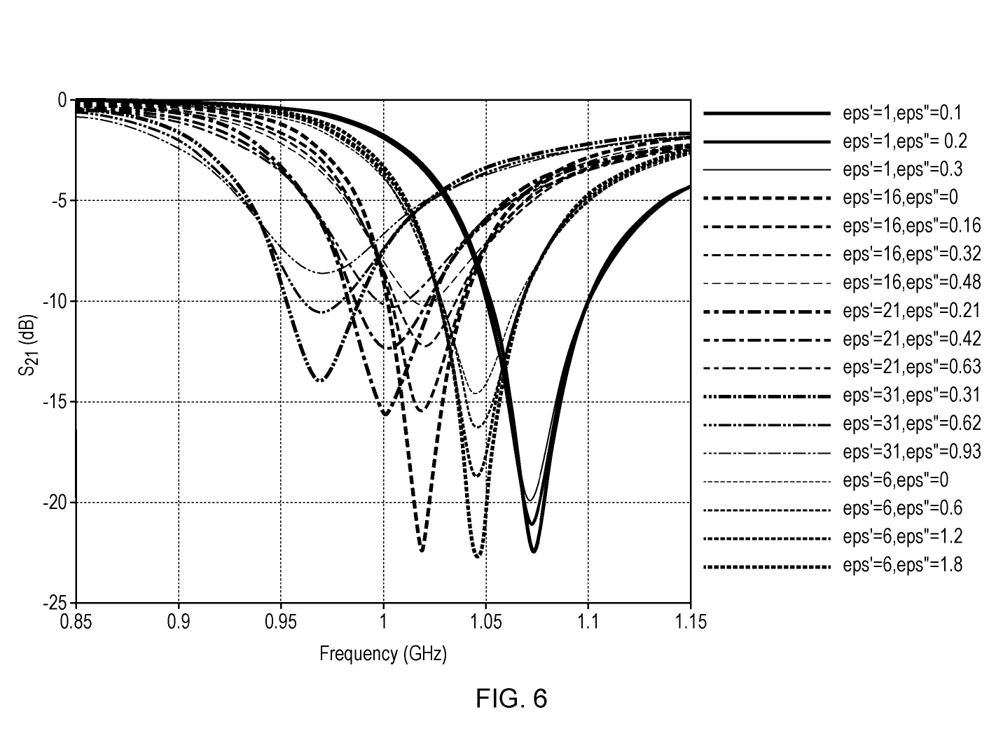

To extract the relative permittivity of the graphene oxide under various humidities, graphene oxide was mimicked in a simulation by a thin dielectric layer, having exactly the same size, thickness and location as that shown in FIG. 1(a). The transmission coefficients of the resonator at five different sets of relative permittivity (εᵣ=ε′−iε″)) at 1 GHz were simulated and are shown in FIG. 6. Each set of curves in FIG. 6 contains the same real part (ε′) but various imaginary parts (ε″) of the relative permittivity. It can be observed that for the same the resonance frequency does not change much with ε″. This is because ε″, which is related to the material loss tangent (tan δ=ε″/ε′), mainly affects the Q factor of the resonator. The simulations reveal that the changes of relative permittivity give rise to a clearly identifiable change to the transmission performance of the resonator. The permittivity of the graphene oxide can be extracted by comparing the experimental measurements and full electromagnetic wave simulations.

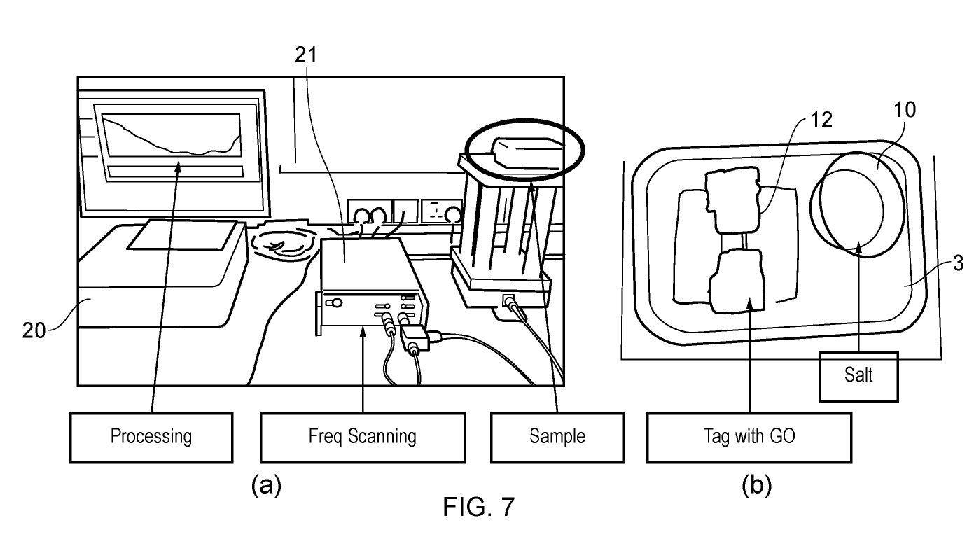

FIG. 7(a) shows an experimental set up comprising a computer 20 and a frequency scanning analyser 21 connected to an RFID tag 12 of embodiments of the present disclosure located in a container 3 with a dish 10 of salt solution. FIG. 7(b) shows the RFID tag 12 and the container 3 in more detail. The RFID tag 12 is as described in connection with FIG. 3.

The present application and invention further includes the subject matter of the following numbered clauses:
1. A sensor, comprising:

an electrical circuit; and

at least one region of oxygenated graphene in electrical contact with the electrical circuit, optionally wherein an insulator of less than 100 μm thickness is present between the electrical circuit and the oxygenated graphene, and wherein the oxygenated graphene is arranged to alter the electrical properties of the circuit in response to environmental changes experienced by the oxygenated graphene.
2. The sensor of clause 1, wherein the environmental changes experienced by the oxygenated graphene include a change in humidity, temperature, and/or the presence or level of a chemical agent.
3. The sensor of clause 3, wherein the presence or level of a chemical agent comprises a carbon dioxide level.
4. The sensor of clause 3, wherein the environmental change is a change in humidity.
5. The sensor of any preceding clause wherein the electrical property of the circuit that are altered in response to the environmental changes is the resistance of the oxygenated graphene.
6. The sensor of any one of clauses 1 to 4, wherein the oxygenated graphene is situated between two conductive plates and the electrical property of the circuit that are altered in response to the environmental changes is the capacitance.
7. An antenna suitable for an RFID transponder, wherein the antenna is in electrical contact with at least one region of oxygenated graphene, optionally wherein an insulator of less than 100 μm thickness is present between the antenna and the oxygenated graphene, and wherein the oxygenated graphene is arranged to alter the electrical properties of the antenna in response to environmental changes experienced by the oxygenated graphene.
8. The antenna of clause 7, wherein the electrical properties of the antenna alter altered by the oxygenated graphene comprise one or more of a resonant frequency of the antenna, an input impedance of the antenna, or a minimum scattering power of the antenna in response to environmental changes experienced by the oxygenated graphene.
9. The antenna of clause 7 or clause 8, wherein the antenna comprises graphene.
10. The antenna of clause 9, wherein the antenna comprises printed graphene.
11. The antenna of any one of clauses 7 to 10, wherein the at least one region of oxygenated graphene is a coating on the antenna.
12. The antenna of any one of claims 7 to 10, wherein the at least one region of oxygenated graphene is embedded in a part of the antenna.
13. The antenna of any one of clauses 7 to 12, comprising two regions of oxygenated graphene in contact with the antenna.
14. The antenna of clause 13, wherein the two regions of oxygenated graphene are arranged at opposite ends of the antenna.
15. The antenna of any one of clauses 7 to 14, wherein the RFID tag is configured to switch on/off to two different states in response to environmental changes experienced by the oxygenated graphene.
16. The antenna of any one of clauses 7 to 15, wherein the antenna and the at least one region of oxygenated graphene form a heterostructure.
17. An RFID transponder comprising:
   an antenna of any one of clauses 7 to 16; and
   an RFID chip coupled to the antenna.
18. The transponder of clause 17, wherein the RFID tag comprises a flexible substrate on which one or more of the antenna, the RFID chip, and at least one region of oxygenated graphene is disposed.
19. A wireless system, comprising an RFID reader and an RFID transponder according to clause 17 and clause 18.
20. A method of detecting an environmental change, comprising:
   detecting a change in the electrical properties of the circuit of a sensor of any one of clauses 1 to 6, the antenna of any one of clauses 7 to 15 or the RFID transponder of any one of clauses 17 to 19;
   comparing the detected change with reference data; and
   determining an environmental change based on the comparison of the detected change and the reference data.
21. The method of clause 20, wherein the environmental change is one or more of humidity, temperature, and/or the presence or level of a chemical agent.
22. The method of clause 21, wherein the presence or level of a chemical agent comprises a carbon dioxide level.
23. The method of clause 21, the environmental change is a change in humidity
24. A method of any one of clauses 20 to 22, wherein the sensor is an RFID transponder according to any one of clauses 17 to 19 and the method comprises:

exciting the RFID tag according to any of clauses 7 to 17 using a first electromagnetic signal;

receiving a re-transmitted second electromagnetic signal from the RFID transponder;

comparing the second electromagnetic signal with reference data; and

determining an environmental change based on the comparison of the second electromagnetic signal and the reference data.
25. The method of clause 24, wherein the reference data is obtained by receiving a reference electromagnetic signal from the RFID transponder when the RFID transponder is experiencing one or more known environmental conditions.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

1. An antenna suitable for an RFID transponder, wherein the antenna is in electrical contact with at least one region of oxygenated graphene, optionally wherein an insulator of less than 100 μm thickness is present between the antenna and the oxygenated graphene, and wherein the oxygenated graphene is arranged to alter the electrical properties of the antenna in response to environmental changes experienced by the oxygenated graphene.

2. The antenna of claim 1 wherein the electrical properties of the antenna alter altered by the oxygenated graphene comprise one or more of a resonant frequency of the antenna, an input impedance of the antenna, or a minimum scattering power of the antenna in response to environmental changes experienced by the oxygenated graphene.

3. The antenna of claim 1 or claim 2, wherein the antenna comprises graphene.

4. The antenna of claim 3, wherein the antenna comprises printed graphene.

5. The antenna of any one of claims 1 to 4, wherein the at least one region of oxygenated graphene is a coating on the antenna.

6. The antenna of any one of claims 1 to 4, wherein the at least one region of oxygenated graphene is embedded in a part of the antenna.

7. The antenna of any one of claims 1 to 6, comprising two regions of oxygenated graphene in contact with the antenna.

8. The antenna of claim 7, wherein the two regions of oxygenated graphene are arranged at opposite ends of the antenna.

9. The antenna of any one of claims 1 to 8, wherein the antenna is an RFID tag configured to switch on/off to two different states in response to environmental changes experienced by the oxygenated graphene.

10. The antenna of any one of claims 1 to 9, wherein the antenna and the at least one region of oxygenated graphene form a heterostructure.

11. An RFID transponder comprising:
an antenna of any one of claims 1 to 10; and
an RFID chip coupled to the antenna.

12. The transponder of claim 11, wherein the RFID transponder comprises a flexible substrate on which one or more of the antenna, the RFID chip, and at least one region of oxygenated graphene is disposed.

13. A wireless system, comprising an RFID reader and an RFID transponder according to claim 11 and claim 12.

14. A sensor, comprising:
an electrical circuit; and
at least one region of oxygenated graphene in electrical contact with the electrical circuit and wherein the oxygenated graphene is arranged to alter the electrical properties of the circuit in response to environmental changes experienced by the oxygenated graphene.

15. The sensor of claim 14, wherein an insulator of less than 100 μm thickness is present between the electrical circuit and the oxygenated graphene.

16. The sensor of claim 14 or 15, wherein the environmental changes experienced by the oxygenated graphene include a change in humidity, temperature, and/or the presence or level of a chemical agent.

17. The sensor of claim 16, wherein the presence or level of a chemical agent comprises a carbon dioxide level.

18. The sensor of claim 16, wherein the environmental change is a change in humidity.

19. The sensor of any of claims 14 to 18, wherein the electrical property of the circuit that are altered in response to the environmental changes is the resistance of the oxygenated graphene.

20. The sensor of any one of claims 14 to 19, wherein the oxygenated graphene is situated between two conductive plates and the electrical property of the circuit that are altered in response to the environmental changes is the capacitance.

21. A method of detecting an environmental change, comprising:
detecting a change in the electrical properties of the circuit of a sensor of any one of claims 14 to 20, the antenna of any one of claims 1 to 10 or the RFID transponder of any one of claims 11 to 12;
comparing the detected change with reference data; and
determining an environmental change based on the comparison of the detected change and the reference data.

22. The method of claim 21, wherein the environmental change is one or more of humidity, temperature, and/or the presence or level of a chemical agent.

23. The method of claim 22, wherein the presence or level of a chemical agent comprises a carbon dioxide level.

24. The method of claim 23, the environmental change is a change in humidity

25. A method of any one of claims 21 to 24, wherein the sensor is an RFID transponder according to any one of claims 11 to 12 and the method comprises:
exciting the antenna according to any of claims 1 to 10 using a first electromagnetic signal;
receiving a re-transmitted second electromagnetic signal from the RFID transponder;
comparing the second electromagnetic signal with reference data; and
determining an environmental change based on the comparison of the second electromagnetic signal and the reference data.

26. The method of claim 25, wherein the reference data is obtained by receiving a reference electromagnetic signal from the RFID transponder when the RFID transponder is experiencing one or more known environmental conditions.
